(19) United States
(12) Patent Application Publication
(10) Pub. No.: US 2025/0006750 A1
(43) Pub. Date: Jan. 2, 2025

(54) PHOTOELECTRIC CONVERSION APPARATUS, MANUFACTURING METHOD, AND EQUIPMENT

(71) Applicant: CANON KABUSHIKI KAISHA, Tokyo (JP)

(72) Inventors: MASAAKI IWANE, Kanagawa (JP); SATOSHI SUZUKI, Tokyo (JP)

(21) Appl. No.: 18/756,721

(22) Filed: Jun. 27, 2024

(30) Foreign Application Priority Data
Jun. 30, 2023 (JP) 2023-107671

(51) Int. Cl. H01L 27/146

(52) U.S. Cl. CPC H01L 27/14605; H01L 27/14609; H01L 27/14627; H01L 27/14689

(57) ABSTRACT

A photoelectric conversion apparatus includes a semiconductor substrate that includes at least one pixel having a plurality of photoelectric conversion elements configured to receive light from a common microlens, wherein the semiconductor substrate includes a first surface that is formed of light-receiving surfaces of the plurality of photoelectric conversion elements and a second surface that faces the first surface, and the first surface has a concave shape, and at least a portion of the first surface is inclined with respect to the second surface.

### BACKGROUND

### Field

The present disclosure relates to a photoelectric conversion apparatus, a manufacturing method, and equipment.

### Description of the Related Art

Japanese Patent Laid-Open No. 2007-281296 discusses a solid-state imaging apparatus that can detect the directivity of incident light by two photoelectric conversion regions provided in one pixel to detect the phase difference of the incident light.

The solid-state imaging apparatus discussed in Japanese Patent Application Laid-Open No. 2007-281296 has a problem in that the ability to detect the angle and directivity of light from a subject is not sufficient, and thus the ability to detect the phase difference of light from the subject is also insufficient.

### SUMMARY

In view of this, the present disclosure is directed to providing a photoelectric conversion apparatus that is improved in the ability to detect the angle and directivity of light from a subject and has a high ability to detect a phase difference, and a method for manufacturing the same.

According to some embodiments, a photoelectric conversion apparatus includes a semiconductor substrate that includes at least one pixel having a plurality of photoelectric conversion elements configured to receive light from a common microlens, wherein the semiconductor substrate includes a first surface that is formed of light-receiving surfaces of the plurality of photoelectric conversion elements and a second surface that faces the first surface, and the first surface has a concave shape, and at least a portion of the first surface is inclined with respect to the second surface.

Further features of the present disclosure will become apparent from the following description of exemplary embodiments with reference to the attached drawings.

### BRIEF DESCRIPTION OF THE DRAWINGS

FIG. 1 is a block diagram of an imaging apparatus according to a first exemplary embodiment.

FIGS. 2A and 2B are schematic diagrams of pixels in the imaging apparatus according to the first exemplary embodiment.

FIG. 3 is a plan view of pixels in the imaging apparatus according to the first exemplary embodiment.

FIG. 4 is a circuit diagram of pixels and a readout circuit in the imaging apparatus according to the first exemplary embodiment.

FIG. 5 is a timing chart of a unit pixel in the imaging apparatus according to the first exemplary embodiment.

FIGS. 6A and 6B are comparison diagrams of the imaging apparatus according to the first exemplary embodiment and the prior art.

FIGS. 7A and 7B are graphs illustrating the relative light amount with respect to a light incident angle Θ and light amount ratio according to the first exemplary embodiment.

FIGS. 8A and 8B are a cross-sectional view and a plan view of pixels in an imaging apparatus according to a second exemplary embodiment.

FIG. 9 is a plan view of pixels in the imaging apparatus according to the second exemplary embodiment.

FIG. 10 is a circuit diagram of pixels and a readout circuit in the imaging apparatus according to the second exemplary embodiment.

FIG. 11 is a timing chart of a unit pixel in the imaging apparatus according to the second exemplary embodiment.

FIGS. 12A and 12B are a cross-sectional view and a plan view of pixels in an imaging apparatus according to a third exemplary embodiment.

FIG. 13 is a plan view of pixels in the imaging apparatus according to the third exemplary embodiment.

FIGS. 14A and 14B are a cross-sectional view and a plan view of pixels in an imaging apparatus according to a fourth exemplary embodiment.

FIGS. 15A and 15B are a cross-sectional view and a plan view of pixels in an imaging apparatus according to a fifth exemplary embodiment.

FIGS. 16A and 16B are a cross-sectional view and a plan view of pixels in an imaging apparatus according to a sixth exemplary embodiment.

FIG. 17 is a plan view of pixels in the imaging apparatus according to the sixth exemplary embodiment.

FIG. 18 is a circuit diagram of pixels and a readout circuit in the imaging apparatus according to the sixth exemplary embodiment.

FIGS. 19A and 19B are a cross-sectional view and a plan view of pixels in an imaging apparatus according to a seventh exemplary embodiment.

FIG. 20 is a plan view of pixels in the imaging apparatus according to the seventh exemplary embodiment.

FIG. 21 is a circuit diagram of pixels and a readout circuit in the imaging apparatus according to the seventh exemplary embodiment.

FIGS. 22A, 22B, and 22C are schematic diagrams of equipment according to an eighth exemplary embodiment.

### DESCRIPTION OF THE EXEMPLARY EMBODIMENTS

In various exemplary embodiments, features, and aspects described below, an imaging apparatus will be mainly taken as an example of a photoelectric conversion apparatus. However, the exemplary embodiments are not limited to an imaging apparatus, and can be applied to other examples of photoelectric conversion apparatuses. Examples of the photoelectric conversion apparatuses include distance measurement apparatuses (apparatuses for distance measurement using focus detection or time of flight (TOF)) and photometering apparatuses (apparatuses for measuring the amount of incident light).

In addition, the disclosure of the present specification includes a complementary set of the concepts described in the present specification. That is, if the present specification includes the statement that “A is greater than B”, for example, it can be said that the present specification also discloses that “A is not greater than B” even though the statement that “A is not greater than B” is omitted. This is because, as a premise, the statement that “A is greater than B” is made in consideration of the case where “A is not greater than B”.

In addition, in the present specification, a plan view is a view from a direction perpendicular to the light incident surface of a semiconductor substrate or to the surface opposite to the light incident surface. Such a plan view corresponds to a two-dimensional plan view obtained by projecting the constituent elements of the photoelectric conversion apparatus onto the surface of a semiconductor substrate.

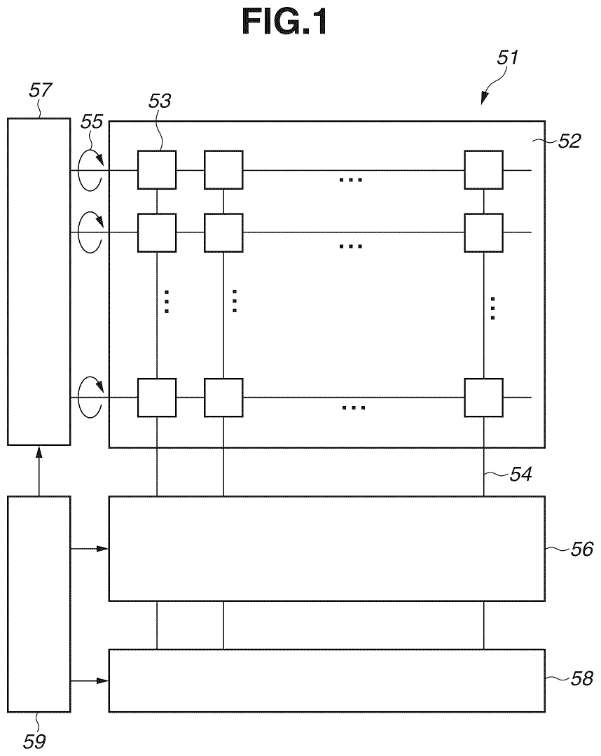

FIG. 1 is a block diagram of the imaging apparatus according to a first exemplary embodiment. An imaging apparatus 51 includes a pixel array part 52, unit pixels 53, column signal lines 54, row signal lines 55, a readout circuit 56, a vertical scanning circuit 57, a horizontal scanning circuit 58, and a timing control circuit 59. A plurality of row signal lines 55 is provided for each of the unit pixels 53. The timing control circuit 59 outputs control pulses to the vertical scanning circuit 57 and the readout circuit 56. Each unit pixel 53 corresponds to one pixel of an image file created through imaging by the imaging apparatus 51.

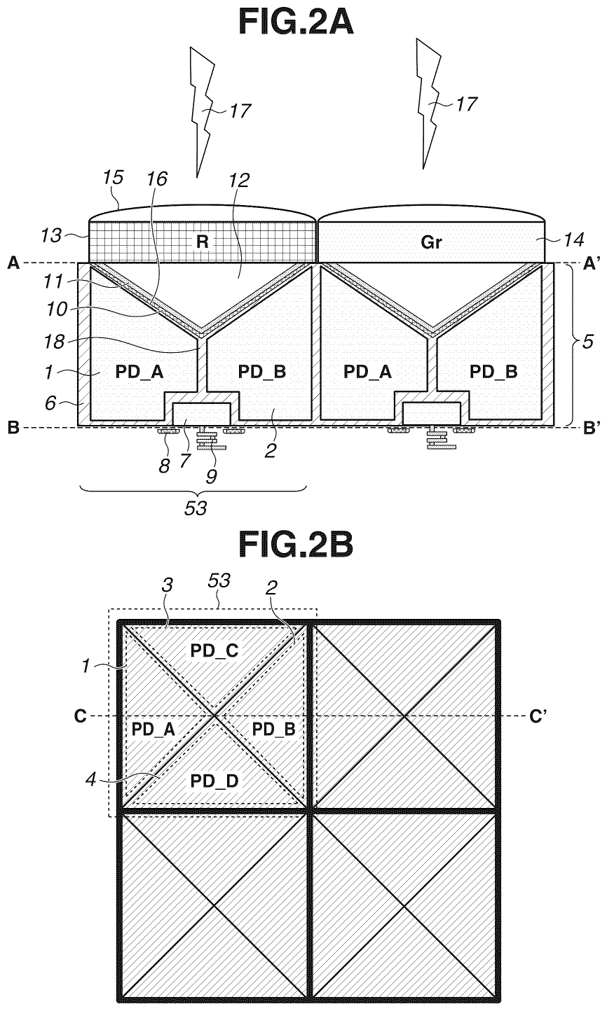

FIGS. 2A and 2B are a cross-sectional view 2A and a plan view 2B of two vertical and two horizontal unit pixels 53 in the pixel array part 52 according to the present exemplary embodiment. Referring to FIGS. 2A and 2B, four photo diodes, PD_A, PD_B, PD_C, and PD_D, belong to each unit pixel 53.

Referring to FIG. 2A, each of the unit pixels 53 includes an N-type region 1 of PD_A, an N-type region 2 of PD_B, a semiconductor substrate 5, a P-type region 6, an N-type floating diffusion region 7, gate electrodes 8 of a transfer metal oxide semiconductor (MOS) transistor, a metallic wire 9, a fixed charge layer 10, an anti-reflection film 11, and an embedded silicon oxide region (filling transparent region) 12.

A red color filter 13 is provided on the unit pixel 53 on the left side of the drawing, and a green color filter 14 is provided on the unit pixel 53 on the right side of the drawing. A microlens 15 is provided on the top of each color filter. A photodiode separation part 18 is provided in the region between PD_A and PD_B. Incident light 17 is incident on the unit pixels 53 from above as illustrated in the drawing.

FIG. 2B is a cross-sectional view taken along line A-A′ in FIG. 2A. That is, FIG. 2B is a plan view as seen from the side where the incident light 17 enters. FIG. 2A is a cross-sectional view taken along line C-C′ in the plan view of FIG. 2B. FIG. 2B illustrates an N-type region 1 of PD_A, an N-type region 2 of PD_B, an N-type region 3 of PD_C, and an N-type region 4 of PD_D.

A light-receiving surface 16 of each unit pixel 53 has a concave shape and is inclined with respect to the back surface of the semiconductor substrate 5. It can be said that a portion of the light-receiving surface 16 is different in angle between the adjacent PDs.

In the present exemplary embodiment, the concave shape of the light-receiving surface 16 between the adjacent PDs is the shape of a square pyramid side surface (hereinafter, called “square pyramid shape”). It can be said that the N-type regions of the photodiodes do not overlap when viewed from the normal direction of the front or back side of the semiconductor substrate 5.

A method for forming the light-receiving surface 16 according to the present exemplary embodiment will be described. The concave shape of the light-receiving surface 16 is formed by anisotropic wet etching or etching using a gray mask. When forming by anisotropic wet etching, the angle of the slope of the square pyramid shape is 54°, for example. At the time of etching, it is desirable to form a resist mask at the boundary part between the unit pixels 53.

A fixed charge layer 10 may be provided on the light-receiving surface 16 to suppress dark current. The materials for the fixed charge layer 10 are preferably oxides of hafnium (HF) such as hafnium oxide (HFO), or oxides of aluminum (AL), titanium (TI), zirconium (ZR), and magnesium (MG). The fixed charge layer 10 is formed by atomic layer deposition (ALD), sputtering, electron beam evaporation, plasma chemical vapor deposition (CVD), or the like.

An anti-reflection film 11 of silicon nitride (SIN) or the like may be provided on the light incident surface of the fixed charge layer 10. As a method for forming the anti-reflection film 11, plasma CVD or the like is used. Silicon oxide (SIO) or the like is provided on the anti-reflection film 11, as a filling transparent region 12 that fills the concave shape. The filling transparent region 12 is formed by plasma CVD or the like.

The red color filter 13 and the green color filter 14 are provided on the filling transparent region 12. Before the formation of the color filters 13 and 14, the filling transparent region 12 is desirably flattened by chemical mechanical polishing (CMP) or the like.

In the cross-sectional view of FIG. 2A, only the red color filter 13 and the green color filter 14 are illustrated. However, a blue color filter may be present on adjacent pixels. Microlenses 15 are provided on the color filters 13 and 14. The unit pixels 53 are formed in the above-described manner.

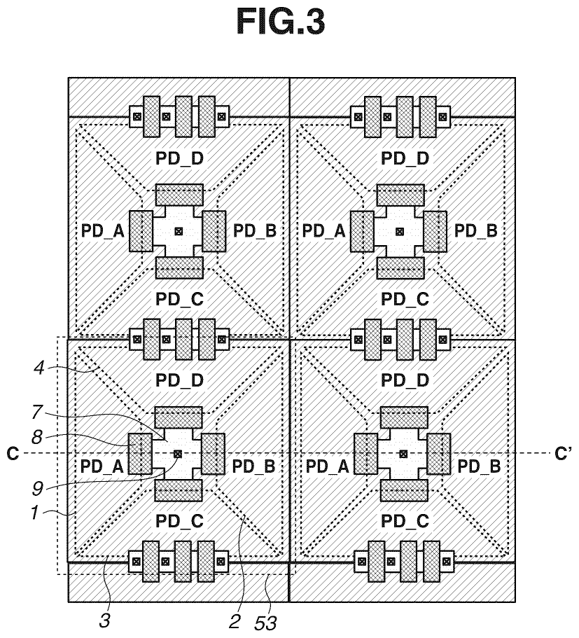

FIG. 3 is the B-B′ cross-sectional view of FIG. 2A. In the present exemplary embodiment, provided on the surface opposite to the light-receiving surface 16 are elements of the readout circuit 56 such as the floating diffusion region 7, the transfer MOS transistor 8, the metal wire 9, and the like. The floating diffusion region 7 constitutes an electric capacitance due to a PN junction with the P-type region 6, and converts the amount of charge accumulated in the electric capacitance into a signal potential.

In the N-type regions 1, 2, 3, and 4 of PD_A, PD_B, PD_C, and PD_D, an N-type impurity is preferably concentrated near the transfer MOS transistor 8 provided on the surface opposite to the light-receiving surface 16. Generating a concentration gradient of impurity in this way produces the advantages that the charges generated in each PD by the incident light 17 can be gathered near the transfer MOS transistor 8, and transferred by the transfer MOS transistor 8 to the floating diffusion region 7 in a short time.

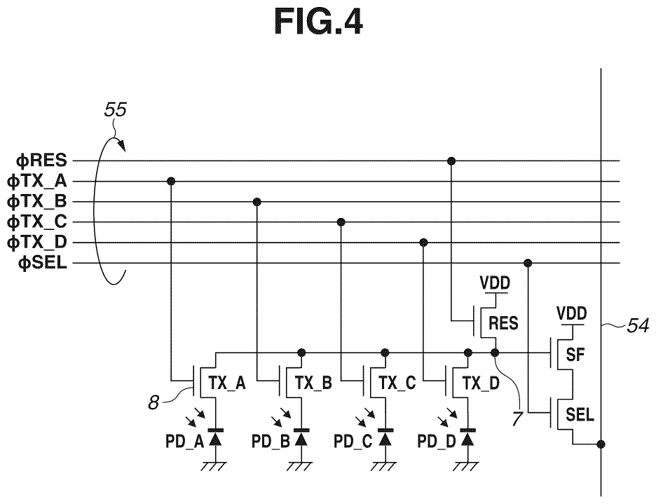

FIG. 4 is a circuit diagram of the pixel and the readout circuit according to the present exemplary embodiment. The readout circuit includes transfer MOS transistors TX_A, TX_B, TX_C, and TX_D, a reset MOS transistor RES, a source follower transistor SF, and a selection MOS transistor SEL.

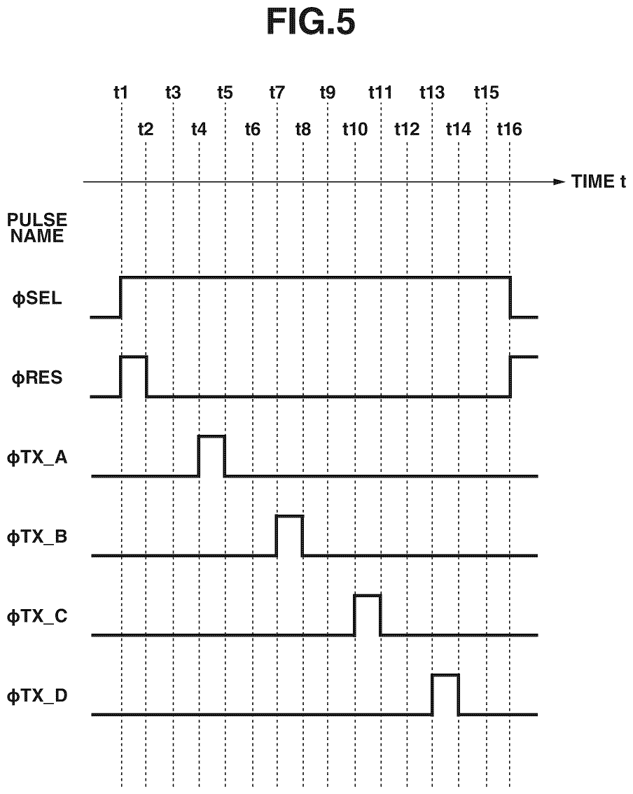

FIG. 5 is a timing chart illustrating the operations of the unit pixel 53 according to the present exemplary embodiment. At time T1, a pulse φSEL to the gate electrode of the selection MOS transistor SEL becomes high, and the unit pixel 53 is selected. At the same time, a pulse φRES to the gate electrode of the reset MOS transistor RES becomes high, and the N-type floating diffusion region 7 is reset.

At time T2, the pulse φRES to the gate electrode of the reset MOS transistor RES becomes low, and the resetting of the floating diffusion region 7 is cancelled. At this time, the noise signal potential of the floating diffusion region 7 is VN. The noise signal potential VN is sent to the column signal lines 54 via the source follower transistor SF, and starts to be analog-to-digital (AD)-converted by the readout circuit 56. At time T3, the AD conversion of the noise signal potential VN of the floating diffusion region 7 completes.

At time T4, a pulse φTX_A to the gate electrode of the transfer MOS transistor TX_A becomes high, and the charge accumulated in PD_A is transferred to the floating diffusion region 7. At time T5, the pulse φTX_A to the gate electrode of the transfer MOS transistor TX_A becomes low, and a signal VA based on the charge accumulated in PD_A appears as a potential of VA+VN in the floating diffusion region 7. At the same time, AD conversion starts in the readout circuit 56. At time T6, the AD conversion of the potential VA+VN completes.

At time T7, a pulse φTX_B to the gate electrode of the transfer MOS transistor TX_B becomes high, and the charge accumulated in PD_B is transferred to the floating diffusion region 7. At time T8, the pulse φTX_B to the gate electrode of the transfer MOS transistor TX_B becomes low, and a signal VB based on the charge accumulated in PD_B appears as a potential of VB+VA+VN in the floating diffusion region 7. At the same time, AD conversion starts in the readout circuit 56. At time T9, the AD conversion of the potential VB+VA+VN completes. At this time, the charge accumulated in PD_A and the charge accumulated in PD_B are added up in the floating diffusion region 7.

At time T10, a pulse φTX_C to the gate electrode of the transfer MOS transistor TX_C becomes high, and the charge accumulated in PD_C is transferred to the floating diffusion region 7. At time T11, the pulse φTX_C to the gate electrode of the transfer MOS transistor TX_C becomes low, and a signal VC based on the charge accumulated in PD_C appears as a potential of VC+VB+VA+VN in the floating diffusion region 7. At the same time, AD conversion starts in the readout circuit 56. At time T12, the AD conversion of the potential VC+VB+VA+VN completes.

At time T13, a pulse φTX_D to the gate electrode of the transfer MOS transistor TX_D becomes high, and the charge accumulated in PD_D is transferred to the floating diffusion region 7. At time T14, the pulse φTX_D to the gate electrode of the transfer MOS transistor TX_D becomes low, and a signal VD based on the charge accumulated in PD_D appears as a potential of VD+VC+VB+VA+VN in the floating diffusion region 7. At the same time, AD conversion starts in the readout circuit 56. At time T12, the AD conversion of the potential VD+VC+VB+VA+VN completes.

At time T14, the pulse φSEL to the gate electrode of the selection MOS transistor SEL becomes low, and the selection of the unit pixel 53 ends.

The potentials VA, VB, VC, and VD are derived by the readout circuit 56 and a signal processing circuit (not illustrated). The potential VA is derived by subtracting VN from the potential VA+VN. The potential VB is derived by subtracting VA+VN from VB+VA+VN. The potential VC is derived by subtracting VB+VA+VN from VC+VB+VA+VN. The potential VD is derived by subtracting VC+VB+VA+VN from VD+VC+VB+VA+VN.

The directivity of the incident light 17 in the horizontal direction of the pixel array part 52 can be derived from the difference between the potentials VA and VB. In addition, the directivity of the incident light 17 in the vertical direction of the pixel array part 52 can be derived from the difference between the potentials VC and VD. That is, according to the present exemplary embodiment, the directivity of the incident light can be derived as a two-dimensional angle.

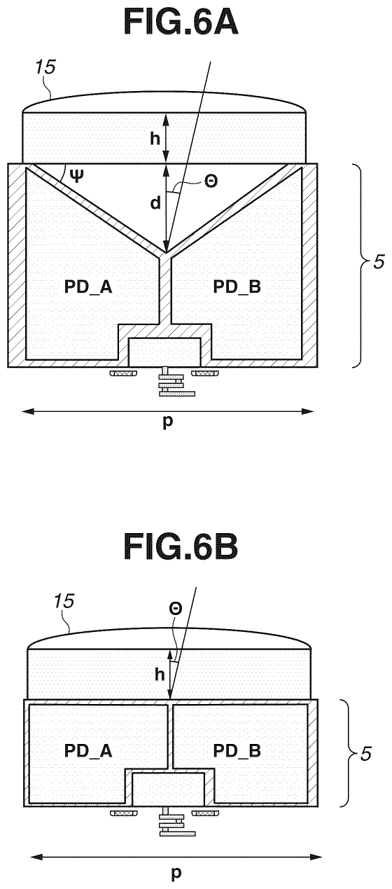

FIGS. 6A and 6B are comparison diagrams for representing the advantageous effects of the present exemplary embodiment. FIG. 6A is a cross-sectional view of the unit pixel according to the present exemplary embodiment, and FIG. 6B is a cross-sectional view of a conventional unit pixel. The light incident surface of the conventional semiconductor substrate 5 is flat without a concave shape, unlike the present exemplary embodiment. In the drawings, p is the pitch of the unit pixel, h is the distance between the surface of the semiconductor substrate 5 and the microlens 15, d is the distance between the apex of the square pyramid shape and the surface of the semiconductor substrate 5, Θ is the incident angle of the incident light, and Ψ is the angle between the ridge of the inverted pyramid and the plane of the semiconductor substrate 5.

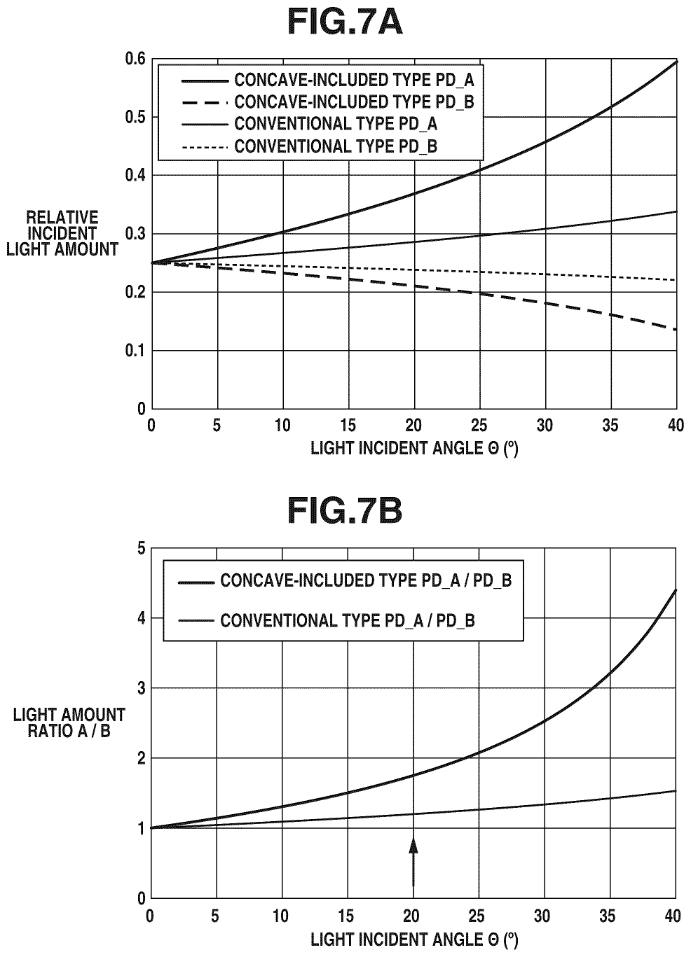

FIGS. 7A and 7B are graphs illustrating the advantageous effects of the present exemplary embodiment. FIG. 7A illustrates the amounts of light incident on PD_A and PD_B among the amounts of light incident on the PDs with respect to the light incidence angle Θ. The light amounts here are the relative amounts of incident light on the PDs, which are normalized by setting the amount of light incident on one unit pixel 53 as 1. For example, if the light incident angle Θ is 0°, a light amount of 0.25 enters each of the PDs PD_A, PD_B, PD_C, PD_D.

In FIG. 7A, the thick lines indicate the light amounts with the concave shape according to the first exemplary example, and the thin lines indicate the light amounts in the conventional type without a concave shape. In this case, the unit pixel pitch p is 4 μm, h is 1 μm, and d is 2 μm (micrometers). In this case, Ψ is 45° (degrees). As the light incidence angle Θ increases, the difference in light amount between PD_A and PD_B becomes larger, but the difference in light amount between PD_A and PD_B increases more noticeably in the type with concave shape than in the conventional type.

FIG. 7B illustrates the light amount ratio of PD_A and PD_B with respect to the light incidence angle Θ. For example, if the light incidence angle Θ=20°, the light amount ratio is 46% higher in the type with a concave shape according to the present exemplary embodiment than in the conventional type. That is, a pixel with a concave shape can respond sensitively to the light incidence angle and has a high ability to detect oblique light. Therefore, the imaging apparatus 51 with a concave shape according to the present exemplary embodiment has a high ability to detect the directivity of the incident light 17. A camera using the imaging apparatus 51 according to the present exemplary embodiment has improvement in the accuracy of phase difference autofocusing.

As can be seen from the graph in FIG. 7B, the larger the light incidence angle Θ, the larger the difference between the present exemplary embodiment and the conventional type. Thus, the imaging apparatus 51 according to the present exemplary embodiment is preferably effective when being applied to situations where the distance between the camera lens and the imaging apparatus 51 is short, for example, when being applied to a smartphone. In addition, the imaging apparatus 51 according to the present exemplary embodiment also has the effect of increasing the range of focus position adjustment for meta image files in which image focus position can be adjusted after image capturing by the camera.

In the above description, the apex of the square pyramid shape is provided at the center of the unit pixel 53 in plan view, but the position of the apex is not limited to this. The apex of the square pyramid shape may be shifted from the center of the unit pixel 53.

The imaging apparatus 51 according to the present exemplary embodiment can allow the color filters 13 and 14 and the microlens 15 to be positioned close to the semiconductor substrate 5, so that optical color mixture can be reduced. The imaging apparatus 51 can also be lowered in profile by decrease in the thickness of the CMOS image sensor. In addition, the N-type regions 1, 2, 3, and 4 of PD_A, PD_B, PD_C, and PD_D can be increased in the area of junction with the P-type region 6, which has the effect of increasing the saturation charge.

In the above description, the unit pixel 53 is structured including the color filters 13 and 14 and the microlens 15, but may be structured not including them. For example, the unit pixels 53 illustrated in FIGS. 2A and 2B may not include the microlens 15 and the color filters 13 and 14. In that case, the imaging apparatus 51 is a monochrome imaging apparatus. Even in this case, the imaging apparatus 51 can be increased in the ability to detect the directivity of the incident light 17.

A second exemplary embodiment is an example in which floating diffusion regions are provided in correspondence with PD_A, PD_B, PD_C, and PD_D. The same reference signs as those in the preceding drawings represent the same components, and description thereof will be omitted.

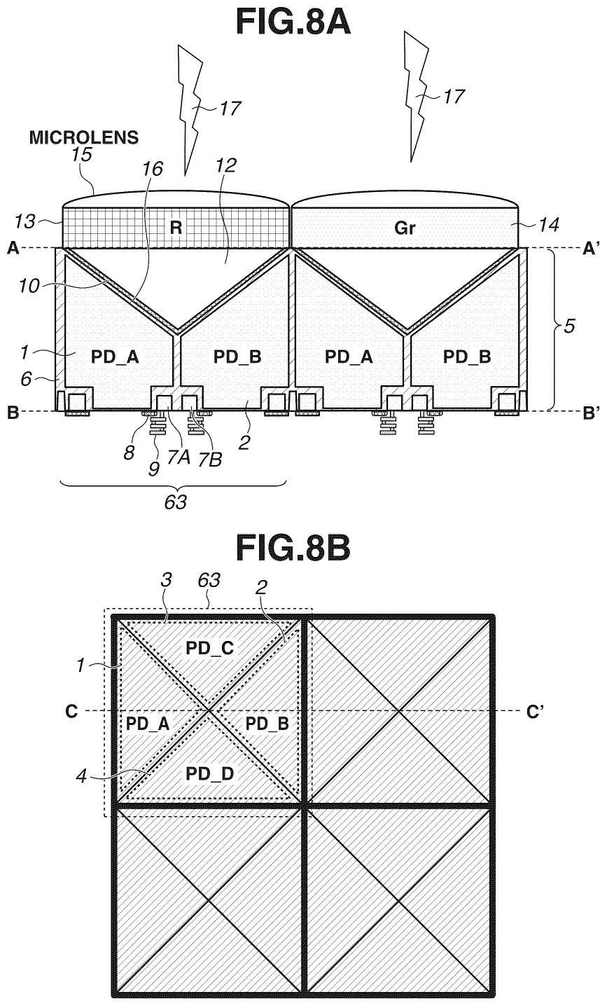

FIGS. 8A and 8B are a cross-sectional view and a plan view of two vertical unit pixels and two horizontal unit pixels in a pixel array part 52 according to the present exemplary embodiment. A unit pixel 63 has a floating diffusion region 7A for PD_A, a floating diffusion region 7B for PD_B, a floating diffusion region 7C for PD_C, and a floating diffusion region 7D for PD_D.

FIG. 8B is a plan view taken along line A-A′ in the cross-sectional view of FIG. 8A and seen from the side where incident light 17 enters. FIG. 8A is a cross-sectional view taken along line C-C′ in the plan view of FIG. 8B. As with the unit pixel 53, the unit pixel 63 includes four photodiodes PD_A, PD_B, PD_C, and PD_D. The light-receiving surface of the unit pixel 63 has a concave shape as in the first embodiment.

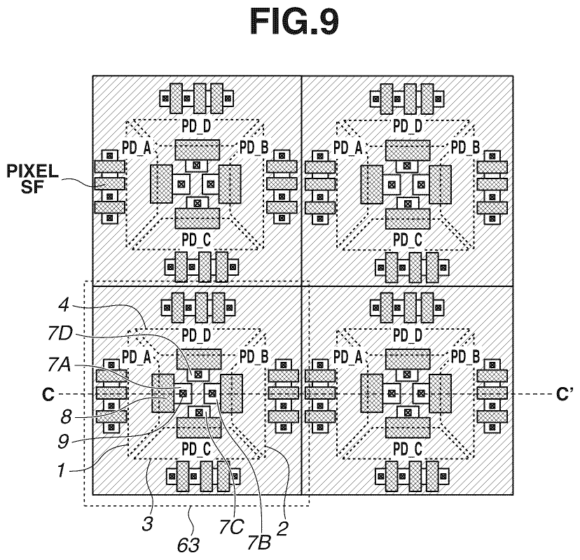

FIG. 9 is a plan view taken along line B-B′ in the cross-sectional view of FIG. 8A and seen from the side opposite to the side where the incident light 17 enters. In the present exemplary embodiment, the floating diffusion regions 7A, 7B, 7C, and 7D are provided for PD_A, PD_B, PD_C, and PD_D, respectively.

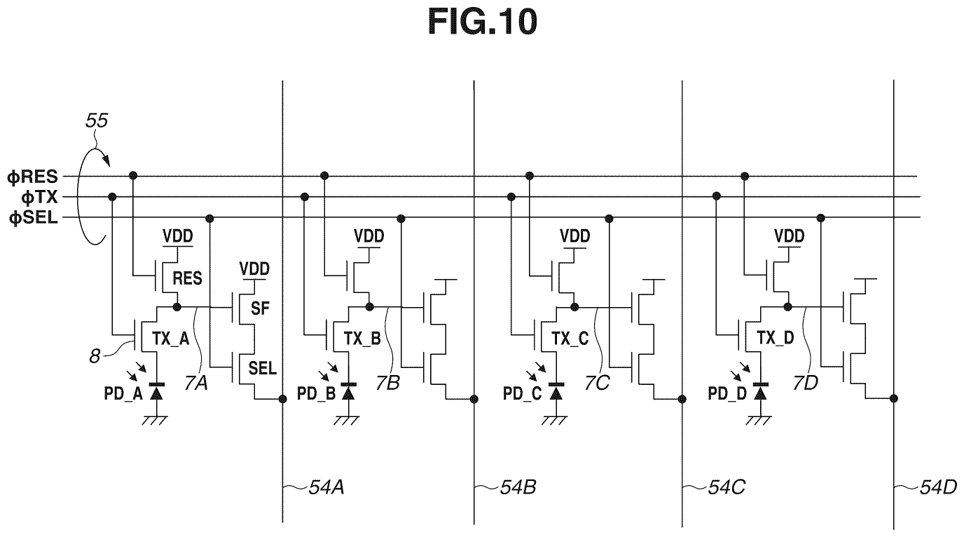

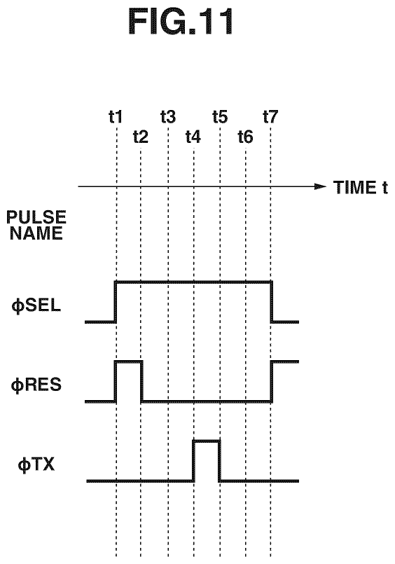

FIG. 10 is a circuit diagram of the pixel and the readout circuit according to the present exemplary embodiment. FIG. 11 is a timing chart of the unit pixel 63 in an imaging apparatus 51 according to the first exemplary embodiment.

At time T1, a pulse φSEL to the gate electrode of a selection MOS transistor SEL becomes high, and the unit pixel 63 is selected. At the same time, a pulse φRES to the gate electrode of a reset MOS transistor RES becomes high, and the N-type floating diffusion region 7 is reset.

At time T2, the pulse φRES to the gate electrode of the reset MOS transistor RES becomes low, and the resetting of the floating diffusion region 7 is cancelled. The noise signal potential of the floating diffusion region 7 at this time is VN. The noise signal potential VN is sent to column signal lines 54A, 54B, 54C, and 54D via a source follower transistor SF, and starts to be AD-converted in the readout circuit 56. At time T3, the AD conversion of the noise signal potential VN of floating diffusion region 7 completes.

At time T4, a pulse φTX to the gate electrodes of transfer MOS transistors TX_A, TX_B, TX_C, and TX_D becomes high, and the charges accumulated in PD_A, PD_B, PD_C, and PD_D are transferred to the floating diffusion regions 7A, 7B, 7C, and 7D.

At time T5, the pulse φTX to the gate electrodes of the transfer MOS transistors TX_A, TX_B, TX_C, and TX_D becomes low, and a signal VA based on the charge accumulated in PD_A appears as a potential of VA+VN in the floating diffusion region 7, and started to be AD-converted in the readout circuit 56. Similarly, a signal VB based on the charge accumulated in PD_B appears as a potential of VB+VN in the floating diffusion region 7B, and started to be AD-converted in the readout circuit 56. The same applies to potentials VC+VN and VD+VN. At time T6, the AD conversion of the potentials VA+VN, VB+VN, VC+VN, and VD+VN completes.

At time T7, the pulse φSEL to the gate electrode of the selection MOS transistor SEL becomes low, and the selection of the unit pixel 63 ends.

In the structure of the present exemplary embodiment, as in the first exemplary embodiment, the ability to detect the directivity of the incident light 17 can be increased. Furthermore, since the imaging apparatus can be lowered in profile, optical color mixture can be reduced. In addition, the N-type regions 1, 2, 3, and 4 of PD_A, PD_B, PD_C, and PD_D become larger in the area of junction with the P-type region 6, which has the effect of increasing the saturation charge.

A third exemplary embodiment is an example in which the area of a concave portion on the light-receiving surface of a photodiode that corresponds to the bottom of a square pyramid is decreased to leave a flat portion. The same reference signs as those in the preceding drawings indicate the same components, and description thereof will be omitted.

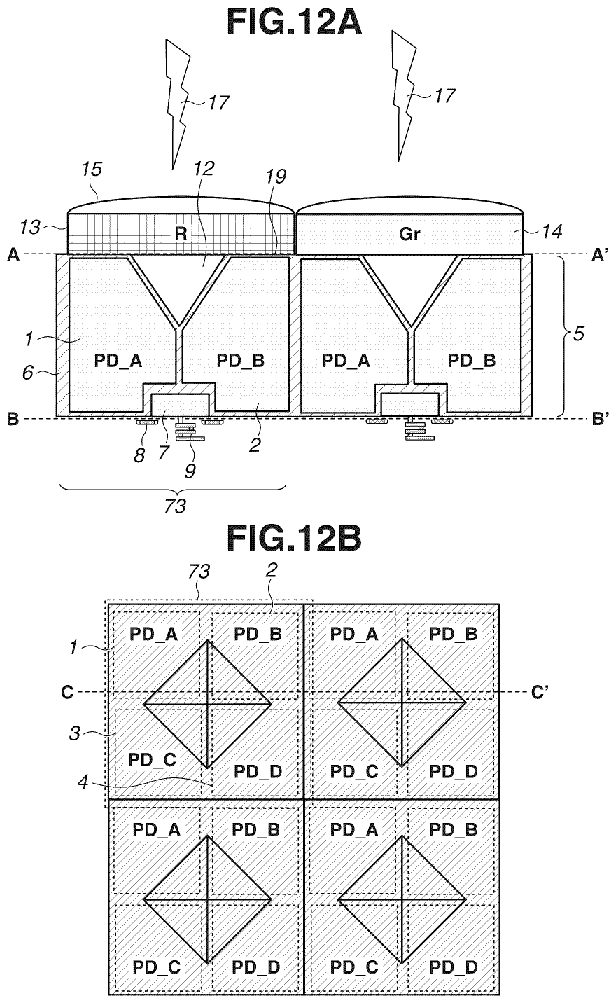

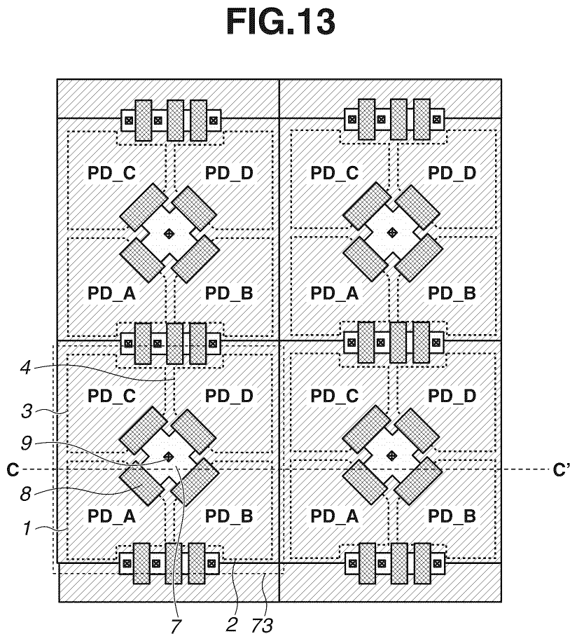

FIGS. 12A and 12B are a cross-sectional view 12A and a plan view 12B of two vertical and two horizontal unit pixels 53 in a pixel array part 52 according to the present exemplary embodiment. The pixel array part 52 has unit pixels 73. FIG. 12B is a plan view taken along line A-A′ in the cross-sectional view of FIG. 12A and seen from the side where incident light 17 enters. FIG. 13 is a plan view taken along line B-B′ in the cross-sectional view of FIG. 12A and seen from the side opposite to the side where the incident light 17 enters.

Like the unit pixel 53, the unit pixel 73 has four photo diodes, PD_A, PD_B, PD_C, and PD_D. In addition, the unit pixel 73 has a concave shape in the center of its light-receiving surface.

The concave shape in the present exemplary embodiment has a smaller area of the bottom of the square pyramid shape than those in the first and second exemplary embodiments. In other words, the concave shape has a large flat part 19. The square pyramid shape is formed by anisotropic wet etching or etching using a gray mask. The flat part 19 is formed by covering with a resist mask during etching so as not to be etched.

Since the thickness of the semiconductor substrate 5 is 2 to 4 μm, for example, the shape of the semiconductor substrate 5 with the flat part left in the present exemplary embodiment improves the mechanical strength of the semiconductor substrate 5 while increasing the ability to detect the directivity of the incident light 17.

A fourth exemplary embodiment is an example in which a flat part is provided at the bottom of a concave shape on the light-receiving surface of a photodiode. The same reference signs as those in the preceding drawings indicate the same components, and description thereof will be omitted.

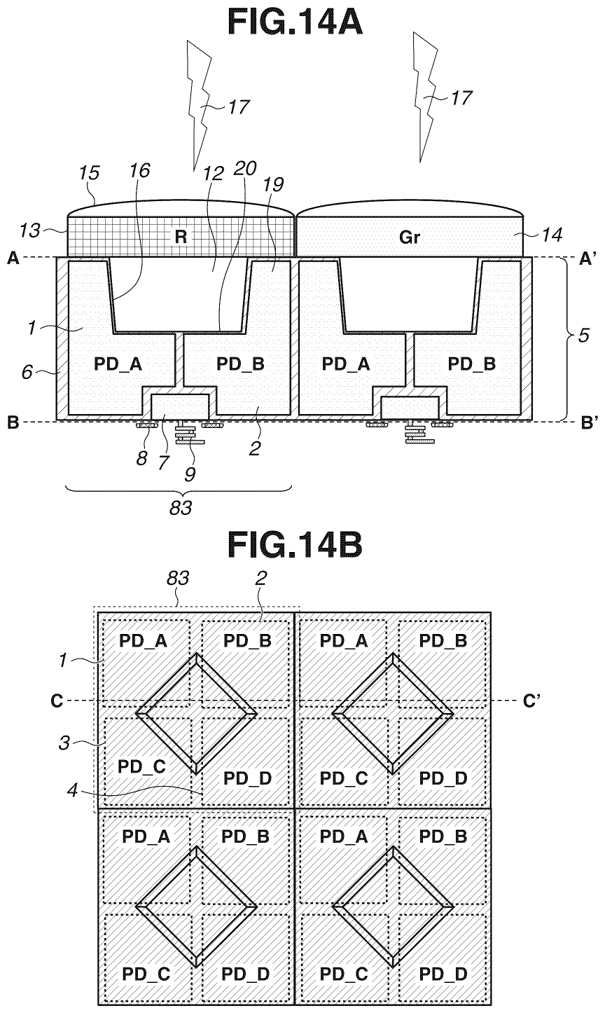

FIGS. 14A and 14B are a cross-sectional view 14A and a plan view 14B of two vertical unit pixels and two horizontal unit pixels in a pixel array part 52 according to the present exemplary embodiment. The pixel array part 52 has unit pixels 83. FIG. 14B is a plan view taken along line A-A′ in the cross-sectional view of FIG. 14A and seen from the side where incident light 17 enters. FIG. 14A is a cross-sectional view taken along line C-C′ in the plan view of FIG. 14B.

In the present exemplary embodiment, the concave shape of the light-receiving surface has a flat part 20 at the bottom. The concave shape is formed by anisotropic wet etching or etching using a gray mask. A flat part 19 is formed by covering with a resist mask during etching so as not to be etched.

With the structure of the present exemplary embodiment, the ability to detect the directivity of the incident light 17 is high, and the area of the junction between the N-type regions 1, 2, 3, and 4 of PD_A, PD_B, PD_C, and PD_D and the P-type region 6 becomes large. This has the effect of increasing the saturation charge.

A fifth exemplary embodiment is an example in which a light-receiving surface and a readout circuit are provided on the same surface of a semiconductor substrate 5. The same reference signs as those in the preceding drawings represent the same components, and description thereof will be omitted.

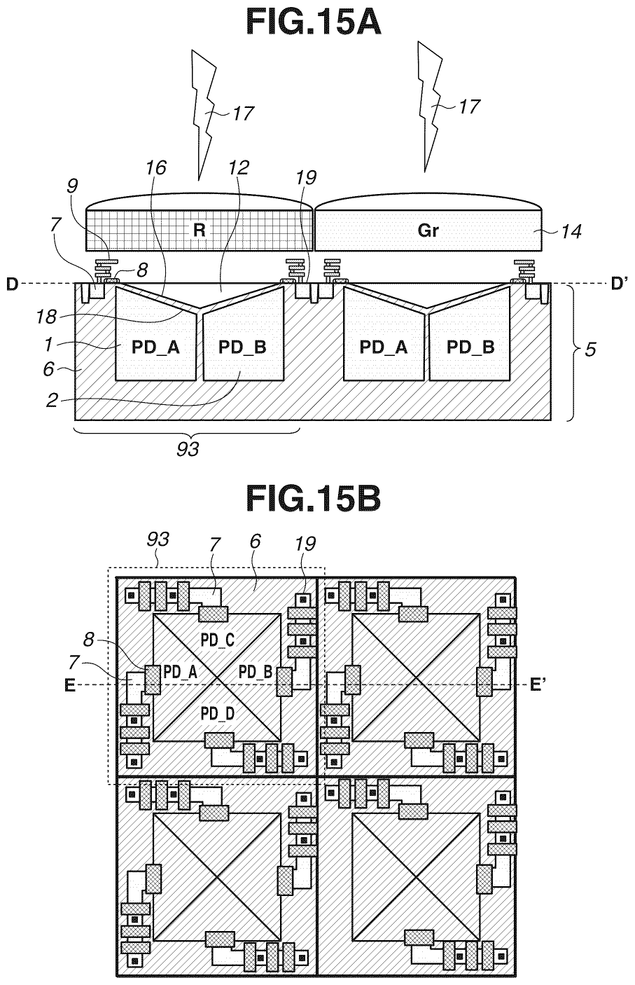

FIGS. 15A and 15B are a cross-sectional view and a plan view of two vertical unit pixels and two horizontal unit pixels in a pixel array part 52 according to the present exemplary embodiment. The pixel array part 52 has unit pixels 93. FIG. 15B is a plan view taken along line D-D′ in the cross-sectional view of FIG. 15A and seen from the side where incident light 17 enters. FIG. 15A is a cross-sectional view taken along line E-E′ in the plan view of FIG. 15B.

In the present exemplary embodiment, the incident surface of incident light 17 and elements of a readout circuit 56 such as a floating diffusion region 7 and a transfer MOS transistor 8 are on the same side of the semiconductor substrate 5. The elements of the readout circuit 56 are provided on a flat part 19 of the semiconductor substrate 5.

The structure of the present exemplary embodiment has the effects of enhancing the ability to detect the directivity of the incident light 17 while reducing manufacturing costs with provision of the light-receiving surface and the pixel readout system on the same surface of the semiconductor substrate 5.

A sixth exemplary embodiment is an example in which the number of photo diodes per unit pixel is changed. The same reference signs as those in the preceding drawings represent the same components, and description thereof will be omitted.

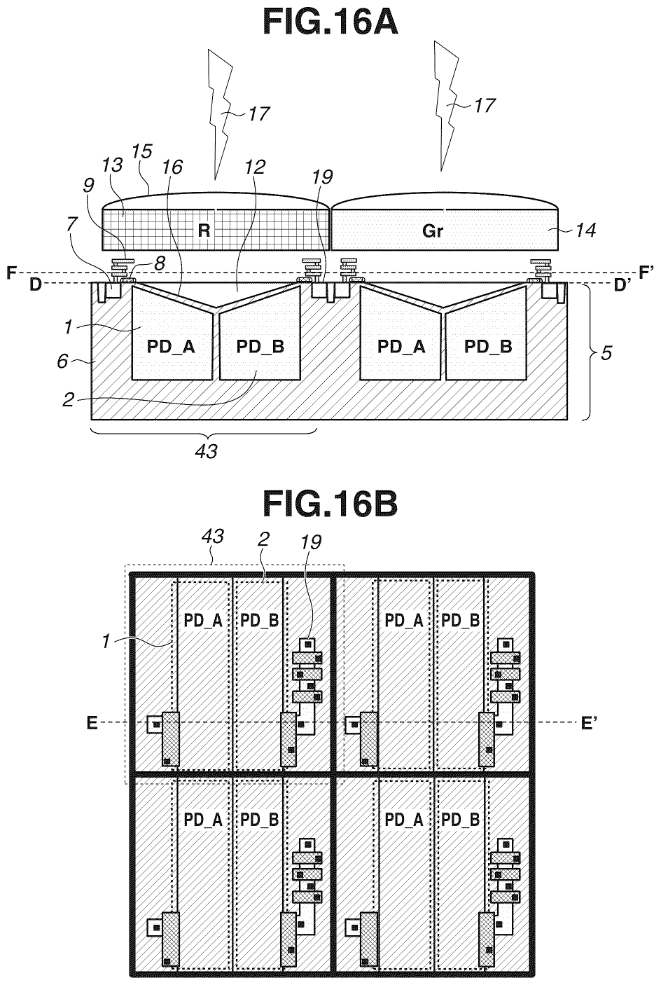

FIGS. 16A and 16B are a cross-sectional view 16A and a plan view 16B of two vertical unit pixels and two horizontal unit pixels in a pixel array part 52 according to the sixth exemplary embodiment. The pixel array part has unit pixels 43. FIG. 16B is a plan view taken along line D-D′ in the cross-sectional view of FIG. 16A and seen from the side where incident light 17 enters.

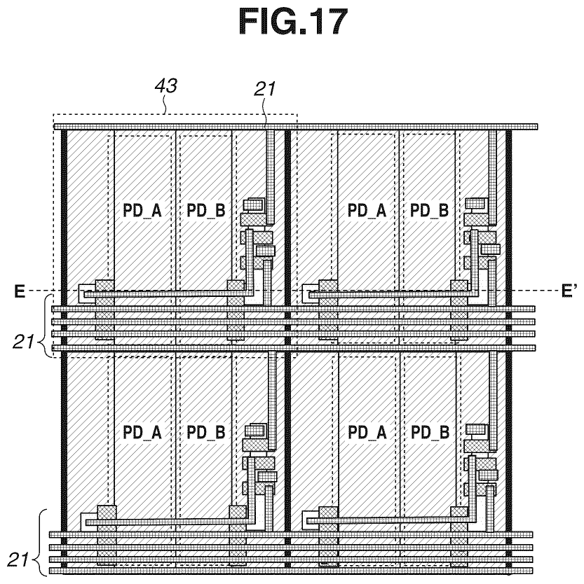

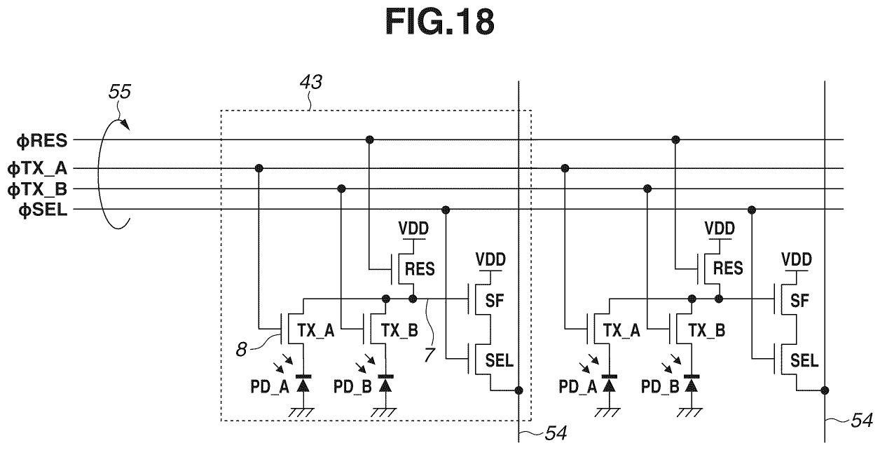

FIG. 16A is a cross-sectional view taken along line E-E′ in the plan view of FIG. 16B. FIG. 17 is a plan view taken along line F-F in the cross-sectional view of FIG. 16A and seen from the side where the incident light 17 enters. FIG. 18 is a circuit diagram of the pixels and readout circuit according to the present exemplary embodiment.

Each unit pixel 43 includes two photo diodes PD_A and PD_B, and has a concave shape in the center of a light-receiving surface.

The two photo diodes may be arranged in the direction in which row signal lines 55 of an imaging apparatus 51 extend, or may be arranged in the direction in which column signal lines 54 of the imaging apparatus 51 extend. With such a structure, the two-dimensional angle of the incident light can be derived.

FIG. 17 illustrates the arrangement of first layer metal wires 21. Metal wires 9 including the first layer metal wires 21 are preferably arranged at the ends of the unit pixels 43 so that as much incident light 17 as possible reaches PD_A and PD_B.

The structure of the present exemplary embodiment makes it possible to increase the ability to detect the directivity of incident light as in the above exemplary embodiments. In addition, only two photo diodes are provided in one unit pixel, which has the effect of increasing the amount of light that enters one photo diode.

A seventh exemplary embodiment is an example in which unit pixels in which a photo diode is divided and unit pixels in which a photo diode is not divided are arranged in a pixel array part. The same reference signs as those in the preceding drawings represent the same components, and description thereof will be omitted.

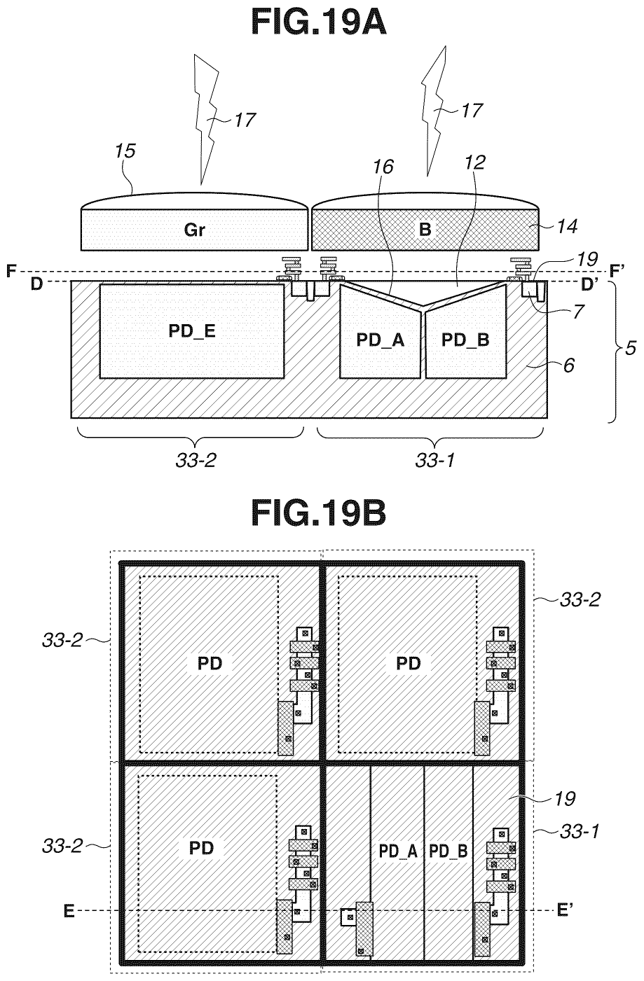

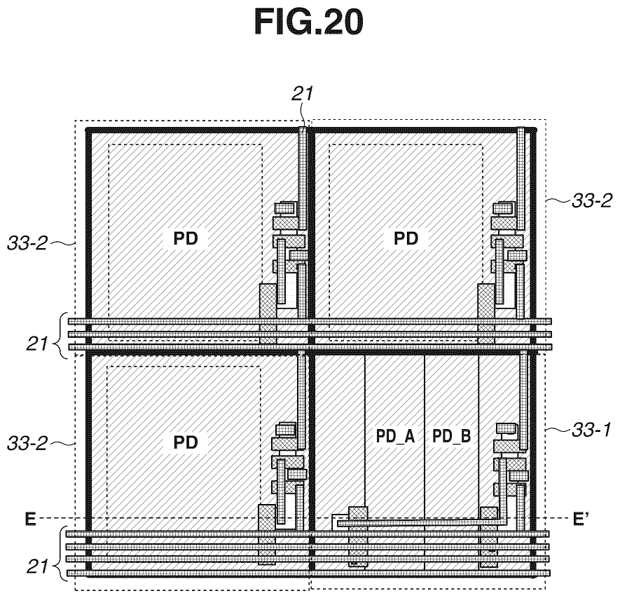

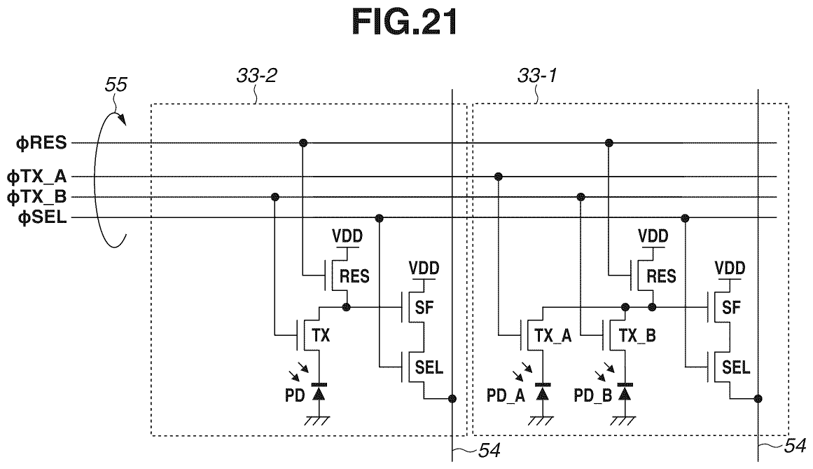

FIGS. 19A and 19B are a cross-sectional view and a plan view of two vertical unit pixels and two horizontal unit pixels in a pixel array part 52 according to the present exemplary embodiment. FIG. 19B is a plan view taken along line D-D′ in the cross-sectional view of FIG. 19A and seen from the side where incident light 17 enters. FIG. 19A is a cross-sectional view taken along line E-E′ in the plan view of FIG. 19B. FIG. 20 is a plan view taken along line F-F in the cross-sectional view of FIG. 19A and seen from the side where the incident light 17 enters. FIG. 21 is a circuit diagram of the pixels and readout circuit according to the present exemplary embodiment.

The pixel array part 52 has unit pixels 33-1 in which the photo diode is divided and unit pixels 33-2 in which the photo diode is not divided. Each unit pixel 33-2 has a photo diode PD_E. Each unit pixel 33-1 has two photo diodes PD_A and PD_B. In other words, the unit pixel 33-2 has fewer photo diodes than the unit pixel 33-1.

In the present exemplary embodiment, the unit pixels 33-1 in which the photo diode is divided constitute only a portion of the pixel array part 52. For example, referring to FIGS. 19A and 19B, only one of the four unit pixels is the unit pixel 33-1 in which the photo diode is divided, and the remaining three unit pixels are the unit pixels 33-2 in which the photo diode is not divided.

FIG. 20 illustrates the arrangement of first layer metal wires 21. Metal wires 9 including the first layer metal wires 21 are arranged at ends of the unit pixels 33-1 and 33-2 so that as much incident light 17 as possible reaches PD_A and PD_B.

Also in the present exemplary embodiment, the ability to detect the directivity of incident light is high. In addition, arranging unit pixels in which the photodiode is not divided has the effect of decreasing the number of metal wires and allowing a large amount of incident light to reach the photodiodes.

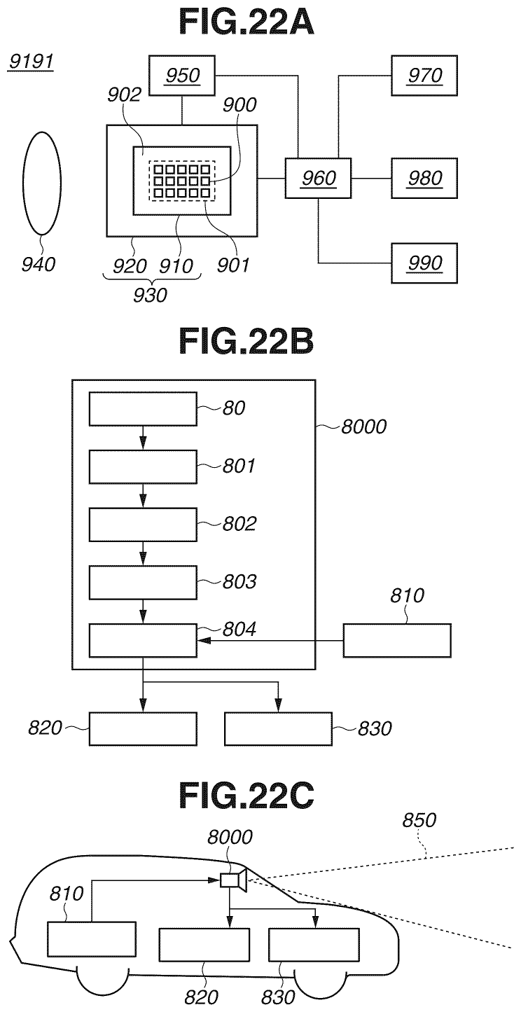

An eighth exemplary embodiment is applicable to any of the first to seventh exemplary embodiments. FIG. 22A is a schematic diagram illustrating equipment 9191 including a semiconductor apparatus 930 according to the present exemplary embodiment. The semiconductor apparatus 930 can be any of the photoelectric conversion apparatus (imaging apparatus) according to the exemplary embodiments described above.

The equipment 9191 including the semiconductor apparatus 930 will be described in detail. The semiconductor apparatus 930 can include a semiconductor device 910. The semiconductor apparatus 930 can include a package 920 that accommodates the semiconductor device 910, in addition to the semiconductor device 910 having a semiconductor layer. The package 920 can include a base body to which the semiconductor device 910 is fixed and a lid body of glass or the like that faces the semiconductor device 910. The package 920 can further include a bonding member such as a bonding wire or a bump that connects the terminal provided in the base body and the terminal provided in the semiconductor device 910.

The equipment 9191 can include at least any one of an optical apparatus 940, a control apparatus 950, a processing apparatus 960, a display apparatus 970, a storage apparatus 980, and a mechanical apparatus 990. The optical apparatus 940 corresponds to the semiconductor apparatus 930. The optical apparatus 940 is a lens, a shutter, and a mirror, for example, and includes an optical system that guides light to the semiconductor apparatus 930. The control apparatus 950 controls the semiconductor apparatus 930. The control apparatus 950 is a semiconductor apparatus such as an application specific integrated circuit (ASIC), for example.

The processing apparatus 960 may include one or more processors, circuitry, or combinations thereof and processes a signal output from the semiconductor apparatus 930. The processing apparatus 960 is a semiconductor apparatus such as central processing unit (CPU), an ASIC, or the like for constituting an analog front end (AFE) or a digital front end (DFE). The display apparatus 970 is an electroluminescent (EL) display apparatus or a liquid crystal display apparatus that displays information (image) obtained by the semiconductor apparatus 930. The storage apparatus 980 stores the information (image) obtained by the semiconductor apparatus 930. The storage apparatus 980 is a magnetic device or a semiconductor device that stores information (image) obtained by the semiconductor apparatus 930. The storage apparatus 980 is a volatile memory such as a static random access memory (SRAM), a dynamic RAM (DRAM), a non-volatile memory such as a flash memory or a hard disk, or another memory.

The mechanical apparatus 990 has a movable part or a propulsion part such as a motor or an engine. The equipment 9191 displays the signal output from the semiconductor apparatus 930 on the display apparatus 970, or transmits the same by a communication apparatus (not illustrated) included in the equipment 9191. For this purpose, the equipment 9191 preferably further includes the storage apparatus 980 and the processing apparatus 960, separately from the storage circuit and arithmetic circuit included in the semiconductor apparatus 930. The mechanical apparatus 990 may also be controlled based on a signal output from the semiconductor apparatus 930.

The equipment 9191 is suitable for electronic equipment such as information terminals (for example, smartphones and wearable terminals) and cameras (for example, interchangeable lens cameras, compact cameras, video cameras, and surveillance cameras) that have an imaging function. The mechanical apparatus 990 in a camera can drive components of the optical apparatus 940 for zooming, focusing, and shutter operation. Alternatively, the mechanical apparatus 990 in a camera can move the semiconductor apparatus 930 for anti-vibration operation.

The equipment 9191 can also be transportation equipment such as a vehicle, a ship, or a flight vehicle (such as a drone or an aircraft). The mechanical apparatus 990 in transportation equipment can be used as a movement apparatus. The equipment 9191 as transport equipment is suitable for transporting the semiconductor apparatus 930 or for assisting and/or automating driving (maneuvering) by its imaging function. The processing apparatus 960 for assisting and/or automating driving (maneuvering) can perform processing for operating the mechanical apparatus 990 as a movement apparatus based on information obtained by the semiconductor apparatus 930. Alternatively, the equipment 9191 may be medical equipment such as an endoscope, measurement equipment such as a ranging sensor, or analytical equipment such as an electron microscope, office equipment such as a copier, or industrial equipment such as a robot.

According to the exemplary embodiment described above, it is possible to obtain favorable pixel characteristics. Therefore, it is possible to enhance the value of a semiconductor apparatus. Enhancing the value here includes at least one of adding functions, increasing performance, improving characteristics, raising reliability, improving manufacturing yield, reducing environmental impact, cost reduction, downsizing, and weight reduction.

Therefore, if the semiconductor apparatus 930 according to the present exemplary embodiment is used in the equipment 9191, the value of the equipment can also be enhanced. For example, mounting the semiconductor apparatus 930 on transportation equipment makes it possible to achieve excellent performance in capturing images of the outside of the transportation equipment or measuring the external environment. Therefore, for manufacturing and selling transportation equipment, it is advantageous in improving the performance of the transportation equipment to decide to install the semiconductor apparatus according to the present exemplary embodiment on the transportation equipment. In particular, the semiconductor apparatus 930 is suitable for providing driving support to transportation equipment and/or causing the transportation equipment to perform automated driving using information obtained by the semiconductor apparatus.

A photoelectric conversion system and a moving object according to the present exemplary embodiment will be described with reference to FIGS. 22B and 22C.

FIG. 22B illustrates an example of a photoelectric conversion system related to an on-vehicle camera. A photoelectric conversion system 8000 includes a photoelectric conversion apparatus 80. The photoelectric conversion apparatus 80 is the photoelectric conversion apparatus (imaging apparatus) according to any of the above exemplary embodiments. The photoelectric conversion system 8000 includes an image processing unit 801 that performs image processing on a plurality of image data acquired by the photoelectric conversion apparatus 80, and a parallax acquisition unit 802 that calculates parallax (phase difference between parallax images) from the plurality of image data acquired by the photoelectric conversion system 8000.

The photoelectric conversion system 8000 may include an optical system (not illustrated) that guides light to the photoelectric conversion apparatus 80, such as a lens, a shutter, and a mirror, for example. In addition, a plurality of photoelectric conversion units that is almost conjugate to the pupil of the optical system may be arranged in the pixel of the photoelectric conversion apparatus 80. For example, the plurality of photoelectric conversion units that is almost conjugate to the pupil is arranged in correspondence with one microlens. Since the plurality of photoelectric conversion units receives light beams that have passed through different positions in the pupil of the optical system, the photoelectric conversion apparatus 80 outputs image data corresponding to the light beams that have passed through the different positions. Then, the parallax acquisition unit 802 may calculate the parallax using the output image data.

The photoelectric conversion system 8000 also includes a distance acquisition unit 803 that calculates the distance to a target object based on the calculated parallax, and a collision determination unit 804 that determines whether there is a possibility of a collision based on the calculated distance. The parallax acquisition unit 802 and the distance acquisition unit 803 are examples of a distance information acquisition unit that acquires distance information to the target object. That is, the distance information is information on parallax, the amount of de-focusing, and the distance to the target object. The collision determination unit 804 may use any of these pieces of distance information to determine the possibility of a collision. The distance information may be acquired based on time of flight (TOF).

The distance information acquisition unit may be implemented by specially designed hardware, or may be implemented by a software module. In addition, the distance information acquisition unit may be implemented by a field programmable gate array (FPGA), an ASIC, or the like, or may be implemented by a combination of these.

The photoelectric conversion system 8000 is connected to a vehicle information acquisition apparatus 810 and can acquire vehicle information such as vehicle speed, yaw rate, and steering angle. The photoelectric conversion system 8000 is connected to a control electronic control unit (ECU) 820, which is a control device that outputs a control signal to generate a braking force to the vehicle, based on the result of determination by the collision determination unit 804. The photoelectric conversion system 8000 is also connected to a warning apparatus 830 that issues a warning to the driver, based on the result of determination by the collision determination unit 804.

For example, if there is a high possibility of a collision as the result of determination by the collision determination unit 804, the control ECU 820 performs vehicle control to avoid a collision or reduce damage by applying the brakes, releasing the accelerator, suppressing engine output, or the like. The warning apparatus 830 can warn the user by sounding an audible alarm, displaying alert information on the screen of the car navigation system, applying vibration to the seat belt or steering wheel, or the like.

In the present exemplary embodiment, the photoelectric conversion system 8000 captures images of the surroundings of the vehicle, for example, an area ahead or behind. FIG. 22C illustrates the photoelectric conversion system 8000 that is capturing an image of an area ahead of the vehicle (image sensing area 850). The vehicle information acquisition apparatus 810 sends instructions to the photoelectric conversion system 8000 or the photoelectric conversion apparatus 80. This configuration can further improve the accuracy of distance measurement.

In the above-described example, control to avoid collisions with other vehicles is exerted. However, the present disclosure can also be applied to control to automatically drive the own vehicle following other vehicles, control to automatically drive the vehicle so as not to move out of the lane, and others. Furthermore, the photoelectric conversion system 8000 can be applied not only to vehicles such as automobiles, but also to moving bodies (moving apparatuses) such as ships, aircraft, and industrial robots, for example. Each moving body includes one or both of a driving force generation unit that generates driving force used to move the moving body and a rotating body that is mainly used to move the moving body. The driving force generation unit can be an engine, a motor, or the like. The rotating body can be tires, wheels, screw propellers of a ship, propellers of aircraft, or the like. In addition, the photoelectric conversion system 8000 can be applied not only to moving bodies but also to a wide range of equipment that performs object recognition, such as an intelligent transportation system (ITS).

In the specification, expressions such as “A or B”, “at least one of A and B”, “at least one of A or/and B”, “one or more of A or/and B” can include all possible combinations of enumerated items unless explicitly defined otherwise. That is, it is to be understood that the above expressions disclose all cases of including at least one A, including at least one B, and including both at least one A and at least one B. This applies equally to combinations of three or more elements.

### Other Exemplary Embodiments

The above exemplary embodiments are merely examples of implementation of the present disclosure, and the technical scope of the present disclosure should not be construed to be limited by these exemplary embodiments. The present disclosure can be implemented in various forms without departing from its technical idea or main characteristics. For example, combinations of the elements of the above exemplary embodiments are also within the scope of the present disclosure.

Each of the described exemplary embodiments can be modified as appropriate without departing from the technical idea. The disclosure of the specification includes not only what is described in the specification, but also all the matters that can be understood from the specification and the drawings accompanying the specification.

According to at least one exemplary embodiment of the present disclosure, it is possible to provide a technique that improves the ability to detect the angle and directivity of light incident on a photoelectric conversion apparatus.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of priority from Japanese Patent Application No. 2023-107671, filed Jun. 30, 2023, which is hereby incorporated by reference herein in its entirety.

What is claimed is:

1. A photoelectric conversion apparatus comprising a semiconductor substrate that includes at least one pixel having a plurality of photoelectric conversion elements configured to receive light from a common microlens,
wherein the semiconductor substrate includes a first surface that is formed of light-receiving surfaces of the plurality of photoelectric conversion elements and a second surface that faces the first surface, and
the first surface has a concave shape, and at least a portion of the first surface is inclined with respect to the second surface.

2. The photoelectric conversion apparatus according to claim 1,
wherein the pixel has an element separation part that separates the plurality of photoelectric conversion elements from each other, and
wherein the element separation part is provided at a position corresponding to a bottom of the concave shape.

3. The photoelectric conversion apparatus according to claim 1, wherein the plurality of photoelectric conversion elements is provided at positions that do not overlap when viewed from a normal direction of the second surface.

4. The photoelectric conversion apparatus according to claim 1,
wherein the pixel has a floating diffusion region, and
wherein electric charges accumulated in the plurality of photoelectric conversion elements are added up in the floating diffusion region.

5. The photoelectric conversion apparatus according to claim 1, wherein an anti-reflection film is provided on the light-receiving surfaces.

6. The photoelectric conversion apparatus according to claim 1, wherein the pixel has a readout circuit on the second surface of the semiconductor substrate to read out a signal based on a signal charge of the photoelectric conversion elements.

7. The photoelectric conversion apparatus according to claim 6, wherein each of the plurality of photoelectric conversion elements has a higher N-type impurity concentration on a side where the readout circuit is provided than on a side of the light-receiving surface.

8. The photoelectric conversion apparatus according to claim 1, wherein the pixel has a readout circuit between the photoelectric conversion elements and the microlens to read out a signal based on a signal charge of the photoelectric conversion elements.

9. The photoelectric conversion apparatus according to claim 8, wherein each of the plurality of photoelectric conversion elements has a higher N-type impurity concentration on a side where the readout circuit is provided than on a side of the second surface.

10. The photoelectric conversion apparatus according to claim 1, wherein the semiconductor substrate has a plurality of the pixels.

11. The photoelectric conversion apparatus according to claim 10, wherein the plurality of pixels includes a first pixel having two of the photoelectric conversion elements.

12. The photoelectric conversion apparatus according to claim 11, further comprising a row signal line extending in a row direction and a column signal line extending in a column direction,
wherein the first pixel includes a pixel in which the two photoelectric conversion elements are arranged in a direction in which the row signal line extends, and a pixel in which the two photoelectric conversion elements are arranged in a direction in which the column signal line extends.

13. The photoelectric conversion apparatus according to claim 10, wherein the plurality of pixels includes a second pixel having four of the photoelectric conversion elements.

14. The photoelectric conversion apparatus according to claim 11,
wherein the plurality of pixels further includes a third pixel having the photoelectric conversion elements, and
wherein the third pixel includes a smaller number of the photoelectric conversion elements than the first pixel.

15. A photoelectric conversion apparatus that includes at least one pixel having a plurality of photoelectric conversion elements, wherein adjacent photoelectric conversion elements are different in angle of a light incident surface.

16. The photoelectric conversion apparatus according to claim 15, further comprising a microlens,
wherein the pixel includes the plurality of photoelectric conversion elements on a light outgoing side of a common microlens.

17. A manufacturing method of a photoelectric conversion apparatus that includes a semiconductor substrate provided with at least one pixel having a plurality of photoelectric conversion elements on a light outgoing side of a common microlens, the manufacturing method comprising:
etching the semiconductor substrate such that at least a portion of the light-receiving surface of the photoelectric conversion elements provided on a first surface of the semiconductor substrate has a concave shape and is inclined with respect to a second surface of the semiconductor substrate facing the first surface.

18. A manufacturing method of a photoelectric conversion apparatus that includes a semiconductor substrate provided with at least one pixel having a plurality of photoelectric conversion elements, the manufacturing method comprising:
etching the semiconductor substrate such that adjacent photoelectric conversion elements are different in angle of a light-receiving surface.

19. The manufacturing method according to claim 17, wherein the etching is performed by anisotropic wet etching.

20. Equipment comprising the photoelectric conversion apparatus according to claim 1, further comprising at least one of:
an optical apparatus corresponding to the photoelectric conversion apparatus;
a control apparatus configured to control the photoelectric conversion apparatus;
a processing apparatus configured to process a signal output from the photoelectric conversion apparatus;
a display apparatus configured to display information obtained by the photoelectric conversion apparatus;
a storage apparatus configured to store the information obtained by the photoelectric conversion apparatus; and
a mechanical apparatus configured to operate based on the information obtained by the photoelectric conversion apparatus.
